(19) United States
(12) Patent Application Publication
(10) Pub. No.: US 2014/0013036 A1
(43) Pub. Date: Jan. 9, 2014

(54) USER DEVICE HAVING NONVOLATILE RANDOM ACCESS MEMORY AND METHOD OF BOOTING THE SAME

(71) Applicants: Oh-Seong KWON, Hwaseong-si (KR); Chulwoo PARK, Yongin-si (KR); Yunsang LEE, Yongin-si (KR)

(72) Inventors: Oh-Seong KWON, Hwaseong-si (KR); Chulwoo PARK, Yongin-si (KR); Yunsang LEE, Yongin-si (KR)

(21) Appl. No.: 13/915,665

(22) Filed: Jun. 12, 2013

(30) Foreign Application Priority Data
Jul. 9, 2012 (KR) 10-2012-0074716

(51) Int. Cl. G11C 11/406; G06F 12/02; G06F 9/44

(52) U.S. Cl. CPC G11C 11/40615; G06F 9/4401; G06F 12/0246
USPC 711/103; 713/2

(57) ABSTRACT

Disclosed is a method of booting a user device including a nonvolatile random access memory (RAM) and a mode register. The method includes reading a Basic Input/Output System (BIOS) refresh setting during a booting operation, and setting the mode register to a refresh timing mode of the nonvolatile RAM according to the BIOS refresh setting. The refresh timing mode selectively includes a refresh inactivation mode for inactivating a refresh operation of the nonvolatile RAM or a refresh execution mode of multiple refresh execution modes having corresponding different refresh periods for activating the refresh operation of the nonvolatile RAM.

### CROSS-REFERENCE TO RELATED APPLICATIONS

A claim for priority under 35 U.S.C. §119 is made to Korean Patent Application No. 10-2012-0074716, filed Jul. 9, 2012, in the Korean Intellectual Property Office, the entire contents of which are hereby incorporated by reference.

### BACKGROUND

Embodiments of the inventive concepts relate to a semiconductor device, and more particularly, to a user device including a nonvolatile random access memory (RAM) and a method of setting the same.

Semiconductor memory devices may be volatile or nonvolatile. Volatile semiconductor memory devices may perform read and write operations at relatively high speeds, and contents stored therein may be lost at power-off. Nonvolatile semiconductor memory devices retain contents stored therein even at power-off. Nonvolatile semiconductor memory devices therefore are used to store contents that must be retained regardless of whether they are powered.

In recent years, demand has increased for nonvolatile semiconductor memory devices capable of realizing high density and large capacity. An example of such a memory device is flash memory, which is typically included in handheld electronic devices. However, research continues on nonvolatile elements capable of supporting random access and improving performance. Such research includes ferroelectric RAM (FRAM) using ferroelectric capacitors, magnetic RAM (MRAM) using tunneling magneto-resistive (TMR) film, phase change memory devices using chalcogenide alloys, and resistive RAM (RRAM) using variable resistance material as a data storage medium, for example.

There is also interest in randomly accessing over-writable nonvolatile memories used as working memories. For example, research is proceeding on nonvolatile RAM compatible with a variety of computer system interfaces. When nonvolatile RAM is used as a main memory (or, a working memory), compatibility between the nonvolatile RAM and general volatile RAM, such as dynamic RAM (DRAM), must be considered. This requires techniques for providing optimum data integrity and low-power characteristics over maintaining compatibility between the nonvolatile RAM and the general volatile RAM.

### SUMMARY

Exemplary embodiments provide a method of booting a user device including a nonvolatile random access memory (RAM) and a mode register. The method includes reading a Basic Input/Output System (BIOS) refresh setting during a booting operation, and setting the mode register to a refresh timing mode of the nonvolatile RAM according to the BIOS refresh setting. The refresh timing mode selectively includes a refresh inactivation mode for inactivating a refresh operation of the nonvolatile RAM or a refresh execution mode of multiple refresh execution modes having corresponding different refresh periods for activating the refresh operation of the nonvolatile RAM.

Exemplary embodiments of the inventive concept also provide a user device including a central processing unit (CPU), a main memory for the CPU, a memory management unit, and a read only memory (ROM). The main memory includes nonvolatile RAM, and the memory management unit is configured to control the nonvolatile RAM under control of the CPU. The ROM is configured to store a BIOS, which includes a BIOS refresh setting, where a refresh timing mode of the nonvolatile RAM is set by the memory management unit according to the BIOS refresh setting during a booting operation. The refresh timing mode is selected from among a refresh inactivation mode and a plurality of refresh execution modes having corresponding to different refresh periods.

Exemplary embodiments of the inventive concept also provide a device including a nonvolatile RAM, a memory management unit and ROM. The memory management unit is configured to control the nonvolatile RAM, and includes a mode register. The ROM is configured to store a BIOS, including a BIOS refresh setting for providing a refresh timing mode of a refresh operation in the nonvolatile RAM. The mode register is set to activate the refresh operation in response to the refresh timing mode being set to one of a plurality of refresh execution modes, each refresh execution mode having corresponding refresh period that indicates time between refreshing data in the nonvolatile RAM.

### BRIEF DESCRIPTION OF THE FIGURES

Exemplary embodiments will be more clearly understood from the following detailed description taken in conjunction with the accompanying drawings in which like reference numerals refer to like parts unless otherwise specified, and in which:

FIG. 1 is a block diagram schematically illustrating a user device, according to an embodiment of the inventive concept.

FIG. 2 is a table illustrating exemplary BIOS refresh settings for providing a refresh period, according to an embodiment of the inventive concept.

FIG. 3 is a block diagram schematically illustrating a memory management unit and a nonvolatile RAM, according to an embodiment of the inventive concept.

FIG. 4 is a block diagram schematically illustrating a memory management unit and a nonvolatile RAM, according to another embodiment of the inventive concept.

FIG. 5 is a block diagram schematically illustrating a memory management unit and a nonvolatile RAM, according to still another embodiment of the inventive concept.

FIG. 6 is a flow chart illustrating a method of booting a user device, according to an embodiment of the inventive concept.

FIG. 7 is a block diagram schematically illustrating a user device, according to another embodiment of the inventive concept.

FIG. 8 is a diagram illustrating a memory cell included in a nonvolatile RAM, according to an embodiment of the inventive concept.

FIG. 9 is a diagram illustrating a memory cell included in a nonvolatile RAM, according to an embodiment of the inventive concept.

FIG. 10 is a block diagram illustrating a computer system, according to an embodiment of the inventive concept.

### DETAILED DESCRIPTION

Embodiments will be described more fully with reference to the accompanying drawings. The inventive concept, however, may be embodied in various different forms, and should not be construed as being limited only to the illustrated embodiments. Rather, these embodiments are provided as examples so that this disclosure will be thorough and complete, and will fully convey the concept of the inventive concept to those skilled in the art. It should be understood, however, that there is no intent to limit exemplary embodiments to the particular forms disclosed, but conversely, exemplary embodiments are to cover all modifications, equivalents, and alternatives falling within the spirit and scope of the inventive concept. Known processes, elements, and techniques are not described with respect to some of the embodiments of the inventive concept. Unless otherwise noted, like reference numerals denote like elements throughout the attached drawings and written description, and thus descriptions will not be repeated. In the drawings, the sizes and relative sizes of layers and regions may be exaggerated for clarity.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Spatially relative terms, such as “beneath”, “below”, “lower”, “under”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” or “under” other elements or features would then be oriented “above” the other elements or features. Thus, the exemplary terms “below” and “under” can encompass both an orientation of above and below. The device may be otherwise oriented (rotated 90 degrees or at other orientations) and the spatially relative descriptors used herein interpreted accordingly. In addition, it will also be understood that when a layer is referred to as being “between” two layers, it can be the only layer between the two layers, or one or more intervening layers may also be present.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that when an element or layer is referred to as being “on”, “connected to”, “coupled to”, or “adjacent to” another element or layer, it can be directly on, connected, coupled, or adjacent to the other element or layer, or intervening elements or layers may be present. In contrast, when an element is referred to as being “directly on,” “directly connected to”, “directly coupled to”, or “immediately adjacent to” another element or layer, there are no intervening elements or layers present.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having meanings that are consistent with their meanings in the context of the relevant art and/or the present specification and will not be interpreted in an idealized or overly formal sense unless expressly so defined herein.

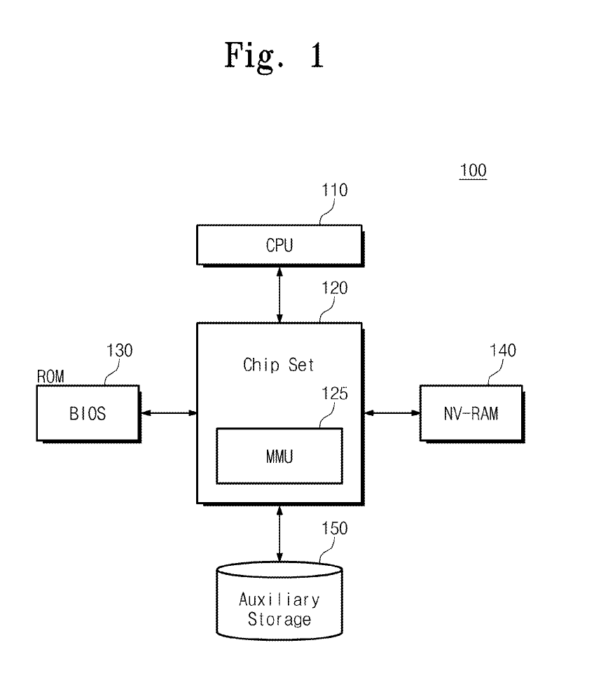

FIG. 1 is a block diagram schematically illustrating a user device, according to an embodiment of the inventive concept. Referring to FIG. 1, a user device 100 may be a computer system, for example. The user device 100 includes a central processing unit (CPU) 110, a chipset 120, read only memory (ROM) 130, nonvolatile random access memory (RAM) 140, and an auxiliary storage device 150. Herein, the nonvolatile RAM 140 may be used as a main memory or working memory of the user device 100.

The CPU 110 is configured to read and execute the Basic Input/Output System (BIOS) and the Operating System (OS) from the ROM 130 and the auxiliary storage device 150, respectively. For example, during a booting operation, the CPU 110 reads and executes a boot program (or, a bootstrap) from the BIOS in the ROM 130. When the boot program is executed, a power-on self-test (POST) operation of the user device 100 may be performed. At this time, various devices including the chipset 120, the nonvolatile RAM 140, and the auxiliary storage device 150 are initialized. After initialization, the CPU 110 reads and decodes the OS from the auxiliary storage device 150, and loads and executes the OS into the nonvolatile RAM 140.

A data processing operation of the user device 100 may be performed. The CPU 110 may control and/or access components connected to a system bus (not shown). For example, during the booting operation, the CPU 110 may access the auxiliary storage device 150 according to a given sequence to drive programs, such as the OS. The CPU 110 also controls a memory management unit (MMU) 125 of the chip set 120 and the auxiliary storage device 150 to read OS data stored in the auxiliary storage device 150 and to store the read OS data in the nonvolatile RAM 140. These control operations are examples, and it is understood that the CPU 110 may manage an entire control operation on the user device 100.

The chipset 120 may include multiple control circuits for controlling devices mounted to the user device 100. For example, the chipset 120 may include the memory management unit 125 for controlling the nonvolatile RAM 140. Alternatively, the memory management unit 125 may be included in the CPU 110. During the booting operation, a BIOS refresh setting for the nonvolatile RAM 140 provided from the BIOS may be stored in a mode register (not shown) of the memory management unit 125. Also, the nonvolatile RAM 140 may be initialized using serial presence detect (SPD) information stored in the nonvolatile RAM 140 and provided to the mode register of the memory management unit 125.

The chipset 120 may be divided into two chipsets, for example, which may be referred to as a North Bridge and a South Bridge. The North Bridge is located close to the CPU 110 to control the CPU 110 and the nonvolatile RAM 140. In this case, the memory management unit 125 is included within the North Bridge. Also, although not shown, expansion card slots for high-speed devices such as Accelerated Graphics Port (AGP) and Peripheral Component Interconnect (PCI) express, may not be included in the North Bridge.

Compared with the North Bridge, the South Bridge is located relatively far from the CPU 110. While the North Bridge controls devices associated with computation, the South Bridge is mainly used to control input/output devices. For example, the South Bridge may control an Integrated Drive Electronics (IDE)/Serial ATA (SATA) port connected to a hard disk drive (HDD) or an optical disk drive (ODD), a Universal Serial Bus (USB) port connected to a keyboard or a mouse, and/or a PCI slot such as a LAN card or a sound card. However, the configuration and role of the chipset 120 is not limited to this disclosure.

In the depicted embodiment, the ROM 130 stores the BIOS, which supports basic process routines of the user device 100. For example, the BIOS may include a start-up routine, a service process routine, and a hardware interrupt process routine. The start-up routine may perform POST and initialization works during the booting operation of the user device 100. The service process routine may process works requested by the OS and/or application programs. In addition, according to various embodiments, the BIOS includes a BIOS refresh setting for controlling a refresh operation of the nonvolatile RAM 140. The BIOS refresh setting, which may be input by a user of the user device 100, is provided to the mode register of the memory management unit 125 during the booting operation.

The nonvolatile RAM 140 may be used as a main memory or a working memory driven at the user device 100. The nonvolatile RAM 140 may support byte access memory, such as DRAM, and may be an over-writable nonvolatile memory device. The nonvolatile RAM 140 used as the working memory may store the OS for driving of the user device 100, application programs, data to be updated, and the like. Herein, the nonvolatile RAM 140 includes multiple chips. The nonvolatile RAM 140 may be formed of a memory module, such as Single In-line Memory Module (SIMM), a Dual In-line Memory Module (DIMM), or a Small outline Dual In-line Memory Module (SoDIMM), for example.

The nonvolatile RAM 140 includes memory elements, such as Electrically Erasable Programmable Read-Only Memory (EEPROM) elements, for storing initialization information (e.g., referred to as SPD information). During the booting operation, the SPD information of a memory module stored in the memory elements may be retrieved and stored in the mode register of the memory management unit 125. It is possible to set size and capacity of the memory module, driving speed, driving operation, arrangement information of chips, module ID, and the like, using the SPD information stored in the memory management unit 125.

The auxiliary storage device 150 may store user data and data such as the OS, application programs, and the like, for example. The auxiliary storage device 150 may be one of an HDD, a solid state drive (SSD), or a hybrid HDD, for example. The auxiliary storage device 150 may be a large-capacity storage device, and may store programs driven at the user device 100, codes, and/or setting data, although the type of large-capacity storage device is not limited to the above examples.

Although not shown in figures, the user device 100 may further include a user interface, a battery, a modem, an application chipset, a camera image processor (CIS), mobile DRAM, and various other features, as would be apparent to one of ordinary skill in the art.

In the illustrative embodiment of the user device 100 described above, it is possible to control a refresh operation of the nonvolatile RAM 140 used as main memory by setting a BIOS refresh setting in the BIOS, e.g., by the user of the user device 100. For example, the BIOS refresh setting may include an Off value (e.g., set as a default mode) for blocking the refresh operation of the nonvolatile RAM 140, or one of a variety of refresh period values (e.g., corresponding to refresh timing modes) for setting a refresh period for the refresh operation of the nonvolatile RAM 140. The refresh period indicates the time between refreshing data in the nonvolatile RAM 140.

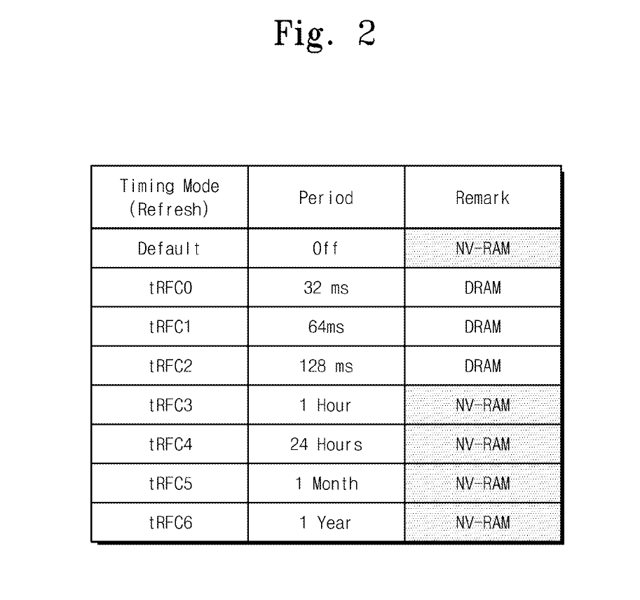

FIG. 2 is a table illustrating an example of BIOS refresh settings for setting refresh timing modes and refresh periods, according to an embodiment of the inventive concept. Referring to FIG. 2, a refresh period may be determined according to selection of a refresh timing mode, e.g., by the user. In the depicted example, refresh timing modes tRFC0 to tRFC2 correspond to DRAM (legacy main memory) and refresh timing modes Default and tRFC3 to tRFC6 correspond to the nonvolatile RAM 140. The refresh timing modes may be selected through BIOS refresh settings.

Each of the refresh timing modes has a corresponding predetermined refresh period. When the DRAM is connected as a legacy main memory, the user may select one of the refresh timing modes tRFC0, tRFC1 and tRFC2, which have corresponding refresh periods of 32 ms, 64 ms and 128 ms, respectively. When the nonvolatile RAM 140 is connected as a main memory, the user may select one of the refresh timing modes Default, tRFC3, tRFC4, tRFC5 and tRFC6. The refresh timing mode Default has no corresponding refresh period of the nonvolatile RAM 140 (indicated as Off), and thus prevents performance of the refresh operation. The refresh timing modes tRFC3, tRFC4, tRFC5 and tRFC6 have corresponding refresh periods of 1 hour, 24 hours, 1 month and 1 year, respectively. One of the refresh timing modes tRFC3 to tRFC6 may be selected, as opposed to Default, when integrity of data stored in the nonvolatile RAM 140 is important. In an embodiment, the refresh timing mode Default may be referred to as a refresh inactivation mode, and each of the refresh timing modes with corresponding refresh periods (e.g., refresh timing modes tRFC0 to tRFC6) may be referred to as a refresh execution mode.

As mentioned above, the main memory may be implemented as a hybrid type of RAM module using both nonvolatile RAM and DRAM. In the hybrid type RAM module, refresh timing modes of the nonvolatile RAM and the DRAM are selected, respectively. That is, the refresh timing mode of the nonvolatile RAM may be set to Default or Off (no refresh operation), and the refresh timing mode of the DRAM may be set to one of the refresh timing modes tRFC0 to tRFC2. The corresponding refresh periods of the nonvolatile RAM and the DRAM may be set in the mode register of the memory management unit 125, accordingly.

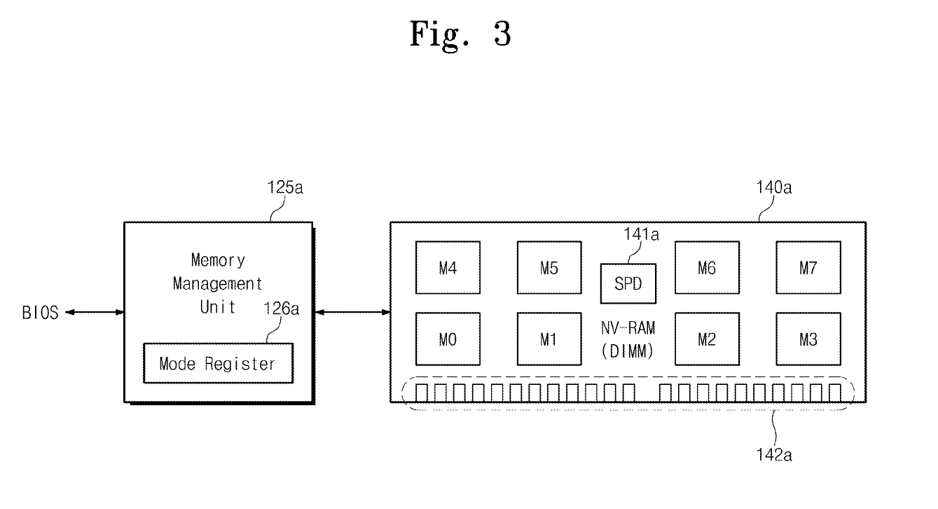

FIG. 3 is a block diagram schematically illustrating a memory management unit and a nonvolatile RAM, according to an embodiment of the inventive concept. Referring to FIG. 3, memory management unit 125a is in communication with nonvolatile RAM 140a. For purposes of illustration, it is assumed that the nonvolatile RAM 140a is implemented by a DIMM module. However, it is understood that the nonvolatile RAM 140a may be implemented by alternative devices, such as a package, an SIMM type, or a SoDIMM type, for example, without departing from the scope of the present teachings.

The memory management unit 125a controls the nonvolatile RAM 140a in accordance with requests from the CPU 110. For example, the memory management unit 125a may control the nonvolatile RAM 140a to program data in the nonvolatile RAM 140a or to read data from the nonvolatile RAM 140a according to corresponding requests from the CPU 110.

The memory management unit 125a includes a mode register 126a, which stores control information for the nonvolatile RAM 140a. A BIOS refresh setting of the nonvolatile RAM 140a, provided by the BIOS during a booting operation, is stored in the mode register 126a. An Off value (default) may be selected, or a specific refresh period value may be selected and provided to the mode register 126a by the BIOS. The memory management unit 125a controls the nonvolatile RAM 140a based on initial data of the mode register 126a.

Further, SPD information may be stored in EEPROM 141a of the nonvolatile RAM 140a. The SPD information is read during the booting operation and stored in the mode register 126a. For example, during the booting operation, the EEPROM 141a may be accessed such that the SPD information is loaded into the mode register 126a under control of the CPU 110. The memory management unit 125a is able to control the nonvolatile RAM 140a based on the SPD information stored in the mode register 126a. For example, the SPD information may include size and capacity of the memory module, driving speed, driving operation, arrangement information of chips, module ID, and other information.

As mentioned above, the nonvolatile RAM 140a may be implemented by a DIMM module. During the booting operation, the nonvolatile RAM 140a may be initialized according to a POST sequence. At initializing, the EEPROM 141a of the nonvolatile RAM 140a, in which the SPD information is stored, may be accessed first. The SPD information stored in the EEPROM 141a is provided to the mode register 126a of the memory management unit 125a.

The nonvolatile RAM 140a also includes multiple nonvolatile memory chips, indicated by representative nonvolatile memory chips M0 to M7. The nonvolatile memory chips M0 to M7 may be mounted on a printed circuit board. Each of the nonvolatile memory chips M0 to M7 may be electrically connected to connection pins 142a formed on the printed circuit board. The connection pins 142a may be electrically connected to the memory management unit 125a and/or a chipset 120 (shown in FIG. 1) through a slot.

In the above description, control information regarding the nonvolatile RAM 140a may be stored in the mode register 126a of the memory management unit 125a. For example, information on whether to perform a refresh operation on the nonvolatile RAM 140a and, when a refresh operation is to be performed, the selected refresh period is stored in the mode register 126a, e.g., in accordance with refresh setting values in the BIOS. The SPD information regarding the nonvolatile RAM 140a may be read from the EEPROM 141a, which is mounted in the nonvolatile RAM 140a, and stored in the mode register 126a.

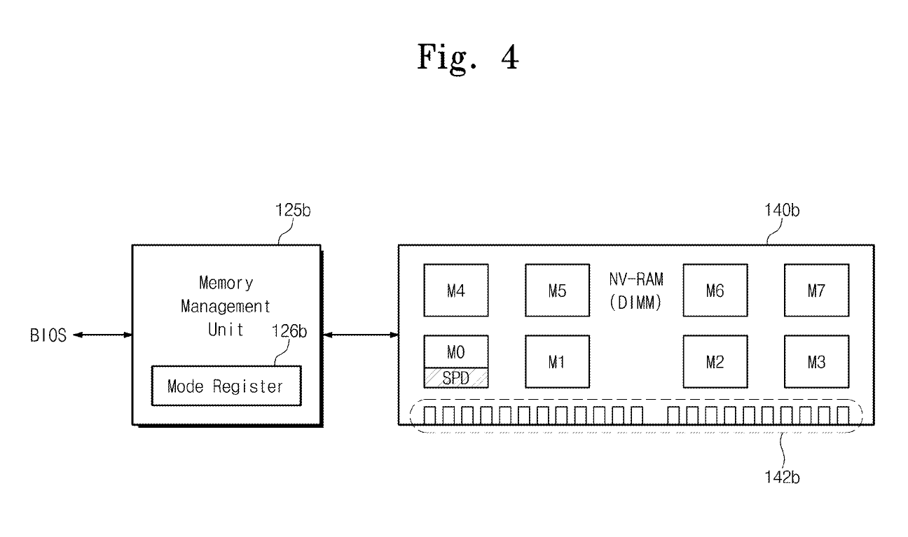

FIG. 4 is a block diagram schematically illustrating a memory management unit and a nonvolatile RAM, according to another embodiment of the inventive concept. Referring to FIG. 4, memory management unit 125b is in communication with nonvolatile RAM 140b, which does not include an EEPROM element for storing SPD information. Instead, the SPD information is stored in one of multiple nonvolatile memory chips M0 to M7, such as the first accessed nonvolatile memory chip (e.g., nonvolatile memory chip M0) from among the nonvolatile memory chips M0 to M7. Stored data is maintained even though power applied to the storage medium, such as spin transfer torque-magneto resistive RAM (STT-MRAM), for example, included in the nonvolatile RAM 140b is interrupted. Each of the nonvolatile memory chips M0 to M7 may be electrically connected to connection pins 142b formed on the printed circuit board, which may be electrically connected to the memory management unit 125b and/or a chipset 120 (shown in FIG. 1) through a slot.

A BIOS refresh setting of the nonvolatile RAM 140b, provided by the BIOS during a booting operation, is stored in a mode register 126b of the memory management unit 125b, as discussed above with regard to the mode register 126a and the memory management unit 125a. An Off value (default) may be selected, or a specific refresh period value may be selected and provided to the mode register 126a by the BIOS. The memory management unit 125b controls the nonvolatile RAM 140b based on initial data of the mode register 126b.

During the booting operation, the SPD information read from at least one of the nonvolatile memory chips M0 to M7 is stored in the mode register 126b. For example, the SPD information may be read from the first accessed nonvolatile memory chip M0 of the nonvolatile RAM 140b and loaded into the mode register 126b during the booting operation. The memory management unit 125b is able to control the nonvolatile RAM 140b based on the SPD information stored in the mode register 126b.

Thus, FIG. 4 provides an example in which the nonvolatile RAM 140b does not include an EEPROM element for storing SPD information. In this case, a region of the memory chip M0 in which the SPD information is stored may be set as a write protection region. Further, a boot program may be set such that the region of the memory chip M0 in which the SPD information is stored is first accessed when initializing the nonvolatile RAM 140b.

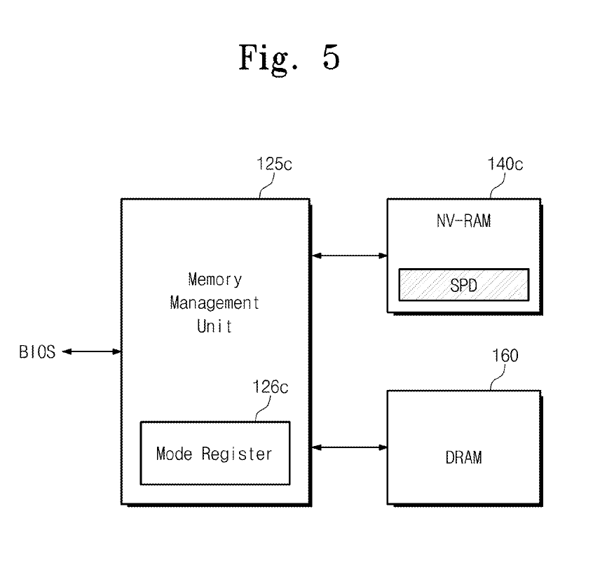

FIG. 5 is a block diagram schematically illustrating a memory management unit and a nonvolatile RAM, according to still another embodiment of the inventive concept. Referring to FIG. 5, memory management unit 125c is in communication with a hybrid type main memory implemented by nonvolatile RAM 140c and volatile DRAM 160. Control information on the nonvolatile RAM 140c and the volatile DRAM 160 may be obtained from SPD information stored in a storage medium of the nonvolatile RAM 140c, such as an EEPROM or a nonvolatile memory chip. The nonvolatile RAM 140c and the DRAM 160 may be formed of chips which are included in one module. Alternatively, the nonvolatile RAM 140c and the DRAM 160 may be formed of independent modules, respectively.

During a booting operation, a BIOS refresh setting provided from the BIOS is stored in a mode register 126c of the memory management unit 125c. An Off value (default) may be selected, or a specific refresh period value may be selected and provided to the mode register 126a by the BIOS. The memory management unit 125c controls the nonvolatile RAM 140c and/or the DRAM 160 based on initial data of the mode register 126c.

During initializing of the main memory, SPD information read from the storage medium of the nonvolatile RAM 140c is stored in the mode register 126c. For example, during the booting operation, the SPD information programmed in a nonvolatile memory chip (e.g., nonvolatile memory chip M0) of the nonvolatile RAM 140c first accessed may be loaded into the mode register 126c. The memory management unit 125c controls the nonvolatile RAM 140c and the DRAM 160 based on the SPD information stored in the mode register 126c.

In a hybrid type of main memory structure implemented using the DRAM 160 and the nonvolatile the RAM 140c, the BIOS refresh settings associated with the DRAM 160 and the nonvolatile RAM 140c are provided from the BIOS. Thus, the memory management unit 125c may perform a refresh operation of the DRAM 160 using a refresh period corresponding to the DRAM 160. In addition, the memory management unit 125c may perform a refresh operation of the nonvolatile RAM 140c using another refresh period corresponding to the nonvolatile RAM 140c.

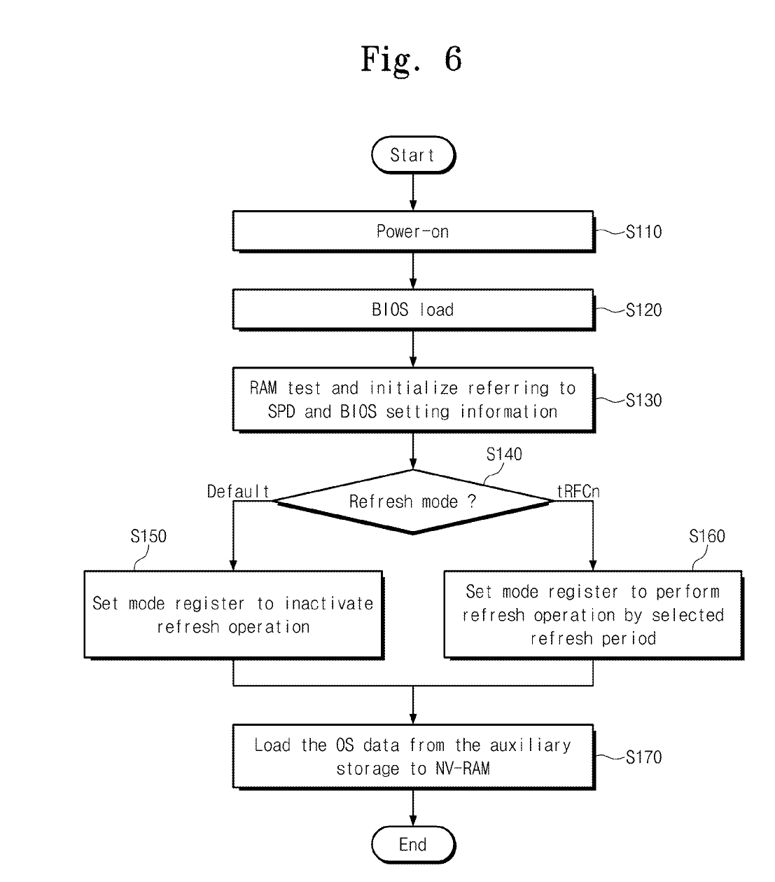

FIG. 6 is a flow chart illustrating a method of booting a user device, according to an embodiment of the inventive concept. During a booting operation, a refresh period of a nonvolatile RAM 140 may be set according to BIOS refresh setting data of the BIOS.

In operation S110, the booting operation begins at power-on of user device 100. When power is supplied to the user device 100, CPU 110 may reset a program counter. In this case, components of the user device 100 may be sequentially accessed according to a booting sequence of the booting operation.

In operation S120, an address first accessed by the CPU 110 according to initialization of the program counter may be set to an address of a boot program of the BIOS to load the BIOS. Thus, as the boot program of the BIOS is executed by the CPU 110, system setting begins.

In operation S130, as the boot program is executed, the CPU 110 performs RAM test (e.g., of nonvolatile RAM 140) and initializes referring to SPD information and BIOS setting information. The CPU 110 may perform a POST operation to check whether the user device 100 is normal. According to the POST operation, the boot program checks whether the CPU 110, the chipset 120, the main memory (nonvolatile RAM 140), and the auxiliary storage device 150 are driven normally. The BIOS also includes a BIOS refresh setting of the nonvolatile RAM 140. The boot program driven by the CPU 110 may set a refresh period of the nonvolatile RAM 140 according to the BIOS refresh setting provided from the BIOS during an initialization process.

In operation S140, a refresh timing mode of the nonvolatile RAM 140 is determined. If the user does not input a refresh timing mode, the refresh timing mode is set to Default (Off), thus inactivating the refresh operation, and the method proceeds to operation S150. Alternatively, the user may actively select the Default refresh timing mode. If the user inputs one of the refresh timing modes tRFCn, the refresh timing mode and corresponding refresh period are set accordingly, and the method proceeds to operation S160.

In operation S150, the CPU 110 sets a mode register of memory management unit 125 to inactivate the refresh operation. In this case, after the booting operation is completed, the memory management unit 125 does not perform the refresh operation on the nonvolatile RAM 140. That is, the memory management unit 125 does not apply a refresh command to the nonvolatile RAM 140 based on a refresh period of the mode register.

In operation S160, the CPU 110 sets the mode register of the memory management unit 125 to activate the refresh operation using the refresh period selected by the user. In this case, after the booting operation is completed, the memory management unit 125 controls the nonvolatile RAM 140 to perform a refresh operation every refresh period.

Once the mode register has been set, it is possible to load data into the nonvolatile RAM 140. Thus, in operation S170, the CPU 110 reads a master boot record (MBR) from a first sector of an auxiliary storage device 150 to load the OS. The boot program may search a bootable partition according to the MBR and execute a boot code. The OS may be loaded into the nonvolatile RAM 140 from the auxiliary storage device 150 using the boot code. Once the OS is executed, operational authority over the user device 100 may be shifted to the OS.

A refresh period setting method of a nonvolatile RAM 140 of a user device 100 according to the BIOS is described above. Generally, when a user selects a refresh inactivation mode (Default) as the refresh timing mode, the refresh operation is turned off, e.g., reducing power consumption. On the other hand, when the user selects one of the refresh execution modes (tRFCn) as the refresh timing mode, the BIOS refresh setting value is set such that data stored in the nonvolatile RAM 140 is refreshed every predetermined refresh period corresponding to the selected refresh timing mode. This may be performed to secure data integrity.

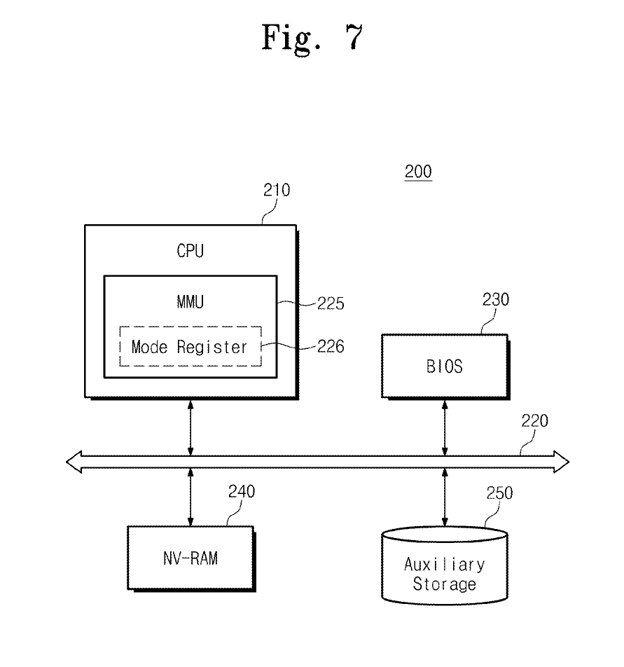

FIG. 7 is a block diagram schematically illustrating a user device, according to another embodiment of the inventive concept. Referring to FIG. 7, a user device 200 includes a CPU 210, which includes a memory management unit 225. Although not shown in FIG. 7, the CPU 210 may further include a graphic processing unit (GPU), for example. The user device 200 further includes ROM 230 storing the BIOS, nonvolatile RAM 240, an auxiliary storage device 250, a user interface 250, and a system bus 220. The CPU 210, the ROM 230, the nonvolatile RAM 240, and the auxiliary storage device 250 are electrically connected to the system bus 220.

During a booting operation of the user device 200, a BIOS refresh setting from the BIOS stored in the ROM 230 is read and stored in the memory management unit 225 of the CPU 210. The BIOS refresh setting may include a refresh timing mode and corresponding refresh period of the nonvolatile RAM 240 set at the BIOS, which is stored in a mode register 226 of the memory management unit 225.

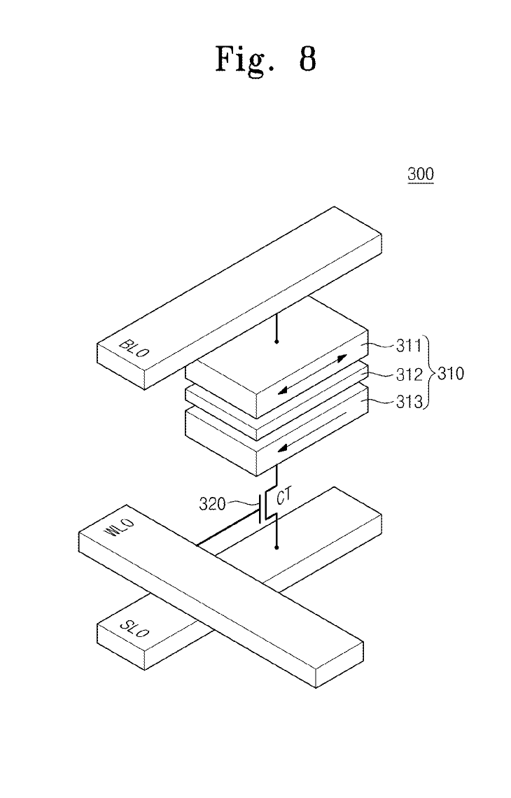

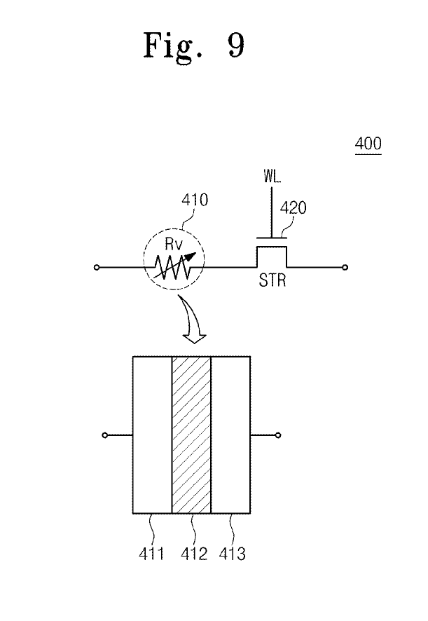

FIGS. 8 and 9 are diagrams illustrating memory cells included in a nonvolatile RAM, according to embodiments of the inventive concept. FIG. 8 depicts a three-dimensional cell structure of STT-MRAM, and FIG. 9 depicts an equivalent circuit of an RRAM structure.

Referring to FIG. 8, an STT-MRAM cell 300 is illustrated as a memory cell of a nonvolatile RAM. The STT-MRAM cell 300 includes a magnetic tunnel junction (MTJ) element 310 and a cell transistor (CT) 320. A gate of the cell transistor 320 is connected to a representative word line WL0. One end of the cell transistor 320 is connected to a representative bit line BL0 through the MTJ element 310. The other end of the cell transistor 320 is connected to a representative source line SL0.

The MTJ element 310 include a pinned layer 313, a free layer 311, and a tunnel layer 312 interposed between the pinned layer 313 and the free layer 311. A magnetization direction of the pinned layer 313 may be fixed, and a magnetization direction of the free layer 311 may be equal to or opposite to that of the pinned layer 313 according to conditions. An anti-ferromagnetic layer (not shown) may be further provided to fix a magnetization direction of the pinned layer 313.

During a write operation of the STT-MRAM cell 300, a voltage is applied to the word line WL0 to turn on the cell transistor 320, and a write current is applied between the bit line BL0 and the source line SL0. During a read operation of the STT-MRAM cell 300, data stored in the MTJ element 310 is determined according to a resistance value measured by applying a turn-on voltage to the word line WL0 to turn on the cell transistor 320 and applying a read current in a direction from the bit line BL0 to the source line SL0.

As mentioned above, FIG. 9 is a circuit diagram illustrating a memory cell of a resistive memory device. Referring to FIG. 9, a memory cell 400 of a resistive memory device includes a variable resistance element 410 and a selection transistor 420.

The variable resistance element 410 includes a variable resistance material for storing data. The selection transistor 420 selectively supplies a current to the variable resistance element 410 according to a bias of a word line WL. As illustrated in FIG. 9, the selection transistor 420 may be an NMOS transistor, for example, although the selection transistor 420 may be other types of switch elements, such as a PMOS transistor, other types of transistors, or a diode.

The variable resistance element 410 includes a pair of electrodes 411 and 413 and a data storage film 412 interposed between the electrodes 411 and 413. The data storage film 412 may be formed of a bipolar resistance storage substance or a unipolar resistance storage substrate. The bipolar resistance storage substance may be programmed to a set or reset state according to a pulse polarity. The unipolar resistance storage substrate may be programmed to a set or reset state by a pulse having the same polarity. The unipolar resistance storage substrate may include a single transition metal oxide such as NiOx or TiOx, and the bipolar resistance storage substance may include a pervoskite material, for example.

STT-MRAM and RRAM are schematically described as memory cells of a nonvolatile RAM. However, the memory cell of the nonvolatile RAM is not be limited to this disclosure. For example, a memory cell of the nonvolatile RAM may be a flash memory cell, a PRAM cell, an MRAM cell, a FRAM cell, or the like.

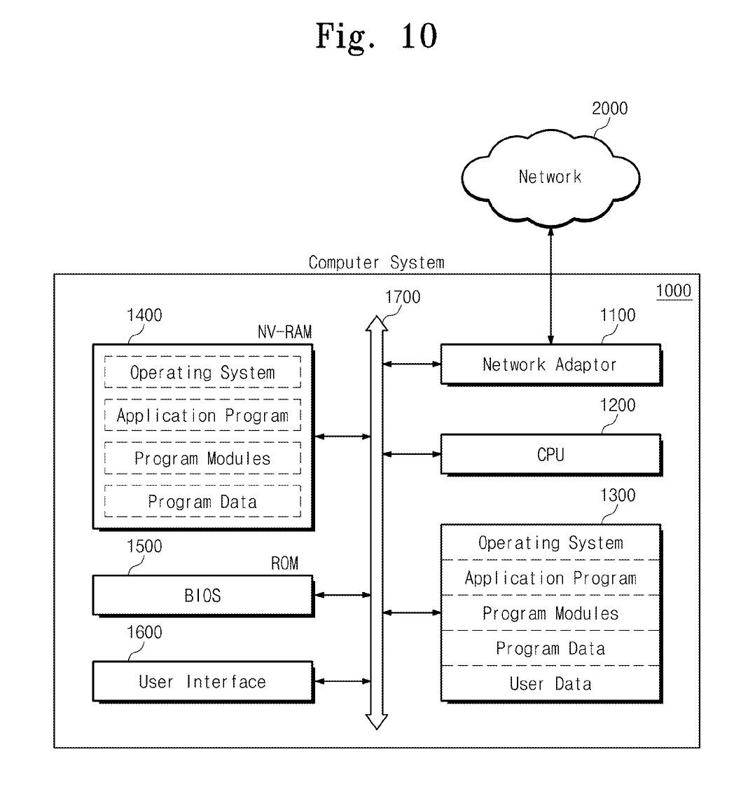

FIG. 10 is a block diagram illustrating a computer system, according to an embodiment of the inventive concept. Referring to FIG. 10, a computer system 1000 includes a network adaptor 1100, a CPU 1200, a large-capacity storage device 1300, nonvolatile RAM 1400, ROM 1500, and a user interface 1600, which are electrically connected to a system bus 1700.

The network adaptor 1100 provides an interface between the computer system 1000 and an external network 2000. The CPU 1200 controls overall operations for driving an operating system and an application program, which are resident on the nonvolatile RAM 1400. The large-capacity storage device 1300 stores data needed for the computer system 1000. For example, the large-capacity storage device 1300 may store an operating system for driving the computer system 1000, an application program, various program modules, program data, user data, and so on.

The nonvolatile RAM 1400 may be used as a working memory of the computer system 1000. Upon booting, the operating system, the application program, the various program modules, and program data needed to drive programs and various program modules read out from the large-capacity storage device 1300 are loaded on the nonvolatile RAM 1400. The ROM 1500 stores a BIOS, which is activated before the operating system is driven upon booting. Information exchange between the computer system 1000 and a user is made via the user interface 1600.

Although not shown in FIG. 10, the computer system 1000 may further include a battery, a modem, an application chipset, a camera image processor (CIS), mobile DRAM, and various other features, as would be apparent to one of ordinary skill in the art.

The large-capacity storage device 1300 may be formed of HDD or hybrid HDD, for example. Alternatively, the large-capacity storage device 1300 may be formed of any of various other types of storage devices, such as a solid state drive (SSD), an MMC card, an SD card, a micro SD card, a memory stick, an ID card, a PCMCIA card, a chip card, a USB card, a smart card, or a CF card, for example.

During a booting operation of the computer system 1000, a refresh period of the nonvolatile RAM 1400 may be adjusted according to a BIOS refresh setting provided from the BIOS. According to the BIOS refresh setting, a refresh operation of the nonvolatile RAM 1400 may be inactivated, e.g., to reduce power consumption, or a refresh period of the nonvolatile RAM 1400 may be set for periodically refreshing the nonvolatile RAM 1400. Periodically refreshing the nonvolatile RAM 140 secures data integrity in view of data retention. Settings of the nonvolatile RAM 1400 may be defined by the BIOS stored in the ROM 1500.

In various embodiments, a nonvolatile RAM and/or memory management unit may be packed using packages such as Package on Package (PoP), Ball grid arrays (BGAs), Chip scale packages (CSPs), Plastic Leaded Chip Carrier (PLCC), Plastic Dual In-Line Package (PDIP), Die in Waffle Pack, Die in Wafer Form, Chip On Board (COB), Ceramic Dual In-Line Package (CERDIP), Plastic Metric Quad Flat Pack (MQFP), Thin Quad Flatpack (TQFP), Small Outline (SOIC), Shrink Small Outline Package (SSOP), Thin Small Outline (TSOP), System In Package (SIP), Multi Chip Package (MCP), Wafer-level Fabricated Package (WFP), Wafer-Level Processed Stack Package (WSP), or other types of packages.

While the inventive concept has been described with reference to illustrative embodiments, it will be apparent to those skilled in the art that various changes and modifications may be made without departing from the spirit and scope of the present inventive concept. Therefore, it should be understood that the above embodiments are not limiting, but illustrative.

What is claimed is:

1. A method of booting a user device comprising a nonvolatile random access memory (RAM) and a mode register, the method comprising:
reading a Basic Input/Output System (BIOS) refresh setting during a booting operation; and
setting the mode register to a refresh timing mode of the nonvolatile RAM according to the BIOS refresh setting, the refresh timing mode selectively comprising a refresh inactivation mode for inactivating a refresh operation of the nonvolatile RAM or a refresh execution mode of a plurality of refresh execution modes having corresponding different refresh periods for activating the refresh operation of the nonvolatile RAM.

2. The method of claim 1, wherein the refresh inactivation mode is set as a default mode.

3. The method of claim 1, wherein the mode register is included in a memory management unit configured to control the nonvolatile RAM.

4. The method of claim 1, further comprising:
reading serial presence detect (SPD) information stored in the nonvolatile RAM.

5. The method of claim 4, further comprising:
storing the read SPD information in the mode register.

6. The method of claim 1, further comprising:
setting the mode register to an additional refresh timing mode of a volatile RAM according to the BIOS refresh setting, the volatile RAM being used as a main memory together with the nonvolatile RAM.

7. The method of claim 6, wherein the additional refresh timing mode of the volatile RAM is provided independently from the refresh timing mode of the nonvolatile RAM.

8. The method of claim 4, wherein the SPD information is read from an Electrically Erasable Programmable Read-Only Memory (EEPROM) of the nonvolatile RAM.

9. The method of claim 4, wherein the SPD information is read from a first accessed nonvolatile memory chip of a plurality of memory chips of the nonvolatile RAM.

10. The method of claim 1, wherein the BIOS refresh setting is input by a user.

11. A user device, comprising:
a central processing unit (CPU);
a main memory for the CPU comprising nonvolatile random access memory (RAM);
a memory management unit configured to control the nonvolatile RAM under control of the CPU; and
a read only memory (ROM) configured to store a Basic Input/Output System (BIOS), including a BIOS refresh setting, wherein a refresh timing mode of the nonvolatile RAM is set by the memory management unit according to the BIOS refresh setting during a booting operation, and the refresh timing mode being selected from among a refresh inactivation mode and a plurality of refresh execution modes having corresponding to different refresh periods.

12. The user device of claim 11, wherein the refresh inactivation mode is set as a default mode.

13. The user device of claim 11, wherein the memory management unit is in the CPU.

14. The user device of claim 11, further comprising:
a chipset comprising the memory management unit.

15. The user device of claim 11, wherein the main memory for the CPU further comprises a volatile RAM, and
wherein an additional refresh timing mode of the volatile RAM is additionally set by the memory management unit according to the BIOS refresh setting during the booting operation, independently from the refresh timing mode of the nonvolatile RAM.

16. The user device of claim 11, wherein the nonvolatile RAM comprises an Electrically Erasable Programmable Read-Only Memory (EEPROM) in which serial presence detect information for driving the nonvolatile RAM is stored.

17. The user device of claim 11, wherein the nonvolatile RAM comprises a plurality of nonvolatile memory chips, and wherein serial presence detect information for driving the nonvolatile RAM is read from a first accessed nonvolatile memory chip of the plurality of nonvolatile memory chips.

18. A device, comprising:
a nonvolatile random access memory (RAM);
a memory management unit configured to control the nonvolatile RAM, the memory management unit comprising a mode register; and
a read only memory (ROM) configured to store a Basic Input/Output System (BIOS), including a BIOS refresh setting for providing a refresh timing mode of a refresh operation in the nonvolatile RAM,
wherein the mode register is set to activate the refresh operation in response to the refresh timing mode being set to one of a plurality of refresh execution modes, each refresh execution mode having corresponding refresh period that indicates time between refreshing data in the nonvolatile RAM.

19. The device of claim 18, wherein the mode register is set to inactivate the refresh operation in response to the refresh timing mode being set to a refresh inactivation mode.

20. The device of claim 18, wherein the refresh inactivation mode is a default refresh timing mode.
